(19) United States
(12) Patent Application Publication
(10) Pub. No.: US 2026/0360672 A1
(43) Pub. Date: Nov. 12, 2026

(54) PLASMA SCREEN FOR SEMICONDUCTOR PLASMA PROCESSING TOOL WITH HIGH PARTICLE BLOCKING RATE AND FLOW CONDUCTANCE

(71) Applicant: Taiwan Semiconductor Manufacturing Company, LTD., Hsinchu (TW)

(72) Inventors: Shao-Chien Hsu, Hsinchu (TW); Kelvin Chiu, Changhua (TW); Wei-Da Chen, Hsinchu (TW); Chien-Liang Chen, New Taipei (TW)

(21) Appl. No.: 19/203,507

(22) Filed: May 9, 2025

(51) Int. Cl. H01J 37/32

(52) U.S. Cl. CPC H01J 37/32495; H01J 37/32513; H01J 37/32834; H01J 2237/3323; H01J 2237/334

(57) ABSTRACT

A semiconductor plasma processing tool includes: a processing chamber including a showerhead and a pump port, the processing chamber configured to excite gas flowed into the processing chamber via the showerhead using radio frequency (RF) and/or microwave energy to form a plasma in the processing chamber; a wafer holder disposed in the processing chamber and configured to hold an associated semiconductor wafer; and an annular plasma screen encircling the wafer holder, the annular plasma screen including a first annular perforated screen and a second annular perforated screen. Perforations of the first annular perforated screen may be first radial slots, and perforations of the second annular perforated screen may be second radial slots offset circumferentially from corresponding first radial slots of the first annular perforated screen.

### BACKGROUND

The following relates to the semiconductor fabrication arts, semiconductor plasma processing tool arts, plasma etching tool arts, plasma deposition tool arts, semiconductor plasma etching and/or plasma deposition arts, and related arts.

In a semiconductor plasma processing tool, a plasma is generated in a plasma processing chamber by exciting a flowing gas (or at least one component thereof) using radio frequency (RF) and/or microwave energy produced by electrodes or an induction coil or the like. Energetic ions of the plasma perform (or facilitate performance of) etching of a wafer and/or deposition of material onto the wafer. However, the energetic ions can also degrade downstream components of the semiconductor plasma processing tool over time, such as degrading material of a pump port of a turbomolecular pump of the tool, and/or degrading components of the pump itself.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a semiconductor plasma processing tool including a plasma screen as disclosed herein.

FIG. 2 diagrammatically illustrates a perspective view of a portion of the plasma screen of the semiconductor plasma processing tool of FIG. 1.

FIG. 3 diagrammatically illustrates a cut view of a portion of the plasma screen of the semiconductor plasma processing tool of FIG. 1.

FIG. 4 diagrammatically illustrates a top view of a portion of the plasma screen of the semiconductor plasma processing tool of FIG. 1.

FIG. 5 diagrammatically illustrates a perspective view of a portion of the plasma screen of the semiconductor plasma processing tool of FIG. 1, with diagrammatically shown representative paths of rebounding particles which land on a surface of the semiconductor wafer forming defects on the semiconductor wafer.

FIG. 6 diagrammatically illustrates a wedge portion of a semiconductor wafer including defects formed by rebounding particles.

FIGS. 7, 8, and 9 diagrammatically plot trendlines of relevant design parameters as a function of geometrical metrics of the plasma screen.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

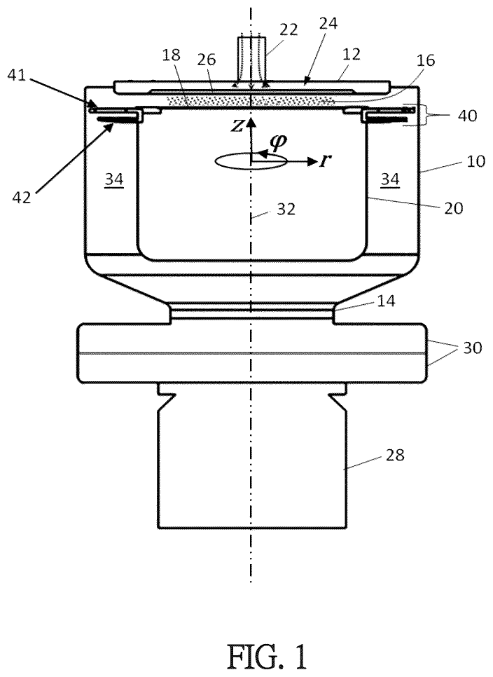

With reference to FIG. 1, a semiconductor plasma processing tool includes a plasma processing chamber 10 having a showerhead 12 and a pump port 14. The processing chamber 10 is also sometimes referred to herein as a plasma processing chamber 10, as a gas injected into the processing chamber 10 by the showerhead 12 flows through the processing chamber 10 is excited (i.e., energized) to form a plasma 16 in the processing chamber by application of radio frequency (RF) and/or microwave energy. The plasma 16 in the processing chamber 10 is operative to etch and/or deposit material (e.g., by physical vapor deposition, PVD) on a semiconductor wafer 18 disposed in the processing chamber and held by an electrostatic chuck (ESC) or other type of wafer holder 20.

The showerhead 12 includes an inlet 22 into which a gas flows. The gas includes one or more gas components comprising molecules that are ionized by the RF or microwave energy to form ions making up the plasma 16, and optionally may also include an inert carrier gas component such as helium, neon, argon, or another noble gas, nitrogen, or a mixture thereof (e.g., forming gas). The gas flows into a plenum 24 of the showerhead 12, and is spread, distributed, and/or diffused into the interior of the processing chamber 10 by way of an array of openings 26 of the showerhead 12.

The plasma processing chamber 10 includes suitable RF and/or microwave components (not shown) for exciting the gas (or at least one component thereof) from the showerhead 12 to form the plasma 16. The RF and/or microwave components for exciting the plasma 16 depends on the type of plasma processing chamber 10. By way of some nonlimiting examples, the plasma processing chamber 10 may be a capacitively coupled plasma (CCP) processing chamber, an inductively coupled plasma (ICP) processing chamber, a transformer coupled plasma (TCP) processing chamber, or an electron cyclotron resonance (ECR) plasma processing chamber. In a CCP chamber the RF and/or microwave energy is coupled to the gas capacitively. In an ICP chamber the RF and/or microwave energy is coupled to the gas inductively. In a TCP chamber the RF and/or microwave energy is coupled to the gas using a transformer. In an ECR chamber the RF and/or microwave energy is coupled to the gas by electron cyclotron resonance. Again, these are nonlimiting illustrative examples.

The pump port 14 is connected with a vacuum pump 28 by way of mating vacuum flanges 30 or another suitably vacuum-tight sealed connection. The illustrative pump port 14 comprises a bellows 14, which provides advantageous mechanical flexibility in the connection of the processing chamber 10 and vacuum pump 28. In some nonlimiting examples, the vacuum pump 28 is a turbomolecular pump (i.e., turbopump) which advantageously can provide dry (i.e., oil-free) pumping with a low ultimate (i.e., base) pressure at no load. However, the vacuum pump 28 may comprise another type of pump such as an oil diffusion pump, an ion pump, a cryogenic pump, a combination thereof, or so forth. The vacuum pump 28 may also include (or be connected with) a roughing pump (not shown) such as a scroll pump, diaphragm pump, screw rotor pump, sorption pump, a combination thereof, or so forth for backing the turbopump or other vacuum pump 28. Such a roughing pump may also be used to initially evacuate the processing chamber 10 to a sufficiently low pressure (e.g., around 1 mTorr) for the turbopump or other high-vacuum pump 28 to operate.

The illustrative semiconductor plasma processing tool has a generally cylindrical shape, insofar as in the illustrative example the plasma processing chamber 10, the showerhead 12 and the wafer holder 20 and secured wafer 18 are approximately rotationally symmetric about a central axis 32 indicated in FIG. 1. A cylindrical coordinate system can be defined with a radial direction r, a circumferential direction φ (also sometimes referred to as an angular direction φ or azimuth direction φ), and an axial direction z as indicated in FIG. 1. While the processing chamber 10, the showerhead 12 and the wafer holder 20 and secured wafer 18 are approximately rotationally symmetric, they may deviate from perfect symmetry in various way. (For example, the semiconductor wafer 18 may include one or more notches or flats sometimes used in commercial semiconductor wafers to designate a crystallographic orientation of a single-crystal silicon, GaAs, or other semiconductor wafer; the processing chamber 10 may include various flanges, sensors, et cetera that break rotational symmetry, and/or so forth). In some embodiments, the wafer holder 20 is configured to rotate the semiconductor wafer 18 about the central axis 32 to improve uniformity of the plasma etching or plasma deposition across the surface of the semiconductor wafer 18. Moreover, semiconductor plasma processing tool embodiments that do not have a generally cylindrical shape are also contemplated.

The gas input to the processing chamber 10 via the showerhead 12 flows through the processing chamber 10 (with a portion of the gas being excited to form the plasma 16) along a flow path of the gas flowing from the showerhead 12 through the plasma processing chamber 10 to the pump port 14. In the nonlimiting illustrative example of FIG. 1 having a generally cylindrical geometry with centrally positioned wafer holder 20, the flow path of the gas goes through an annular plenum 34 defined between the generally cylindrical inner wall of the processing chamber 10 and the generally cylindrical wafer holder 20 which occupies a substantial central portion of the interior of the processing chamber 10; however, this is merely a nonlimiting illustrative example. After passing through the annular plenum 34, the gas flows into the pump port 14 and is exhausted via the vacuum pump 28.

The semiconductor plasma processing tool is designed to position the plasma 16 to be effective in assisting or performing the semiconductor wafer processing (e.g., plasma etching, plasma-assisted etching, plasma deposition, or plasma-assisted deposition) on the semiconductor wafer 18. The plasma 16 can be highly reactive for some materials—hence, the plasma 16 can be effective for certain types of semiconductor processing. Energized ions of the plasma 16 can interact with material on (or near) the surface of the semiconductor wafer 18 physically (i.e., by bombardment with high-speed ions) and/or chemically (where the ionic nature of the ions can promote chemical reactions that might not occur, or might occur less vigorously, for corresponding neutrally charged atoms or molecules). In plasma etching, the physical and/or chemical plasma reactions operate to remove material from the surface of the semiconductor wafer 18. In plasma deposition, the physical and/or chemical plasma reactions operate to deposit material from the gas onto the surface of the semiconductor wafer 18.

While the plasma 16 advantageously promotes the desired etching or deposition operation performed on the semiconductor wafer 18, ions of the plasma 16 can also detrimentally interact with various materials of the semiconductor plasma processing tool. For example, plasma exposure can damage the bellows 14 or other sensitive materials and/or structures of the pump port 14, and/or can damage materials and/or components of the vacuum pump 28. To minimize or eliminate this damage, a plasma screen 40 is arranged upstream of the bellows 14 and downstream of the showerhead 12, along the flow path of gas flowing from the showerhead 12 through the plasma processing chamber 10 to the pump port 14. The plasma screen 40 is interposed along the flow path between the plasma 16 and the bellows 14. The plasma screen 40 reduces or eliminates passage of energetic ions of the plasma 16 to the bellows 14 and/or other downstream components that are susceptible to damage by the plasma.

The plasma processing performed using the semiconductor plasma processing tool can produce particles or particulates that dislodge from the surface of the semiconductor wafer 18 (e.g., as a byproduct of plasma etching of the semiconductor wafer 18); and/or particles or particulates that form by chemical reactions within the plasma 16 or on the walls of the plasma processing chamber 10; and/or particles or particulates that may form and/or be dislodged elsewhere in the processing chamber 10. The gas flow is directed along the gas flow path from the showerhead 12, laterally over the surface of the semiconductor wafer 18 to the periphery of the semiconductor wafer 18 and its holder 20, downward through the annular plenum 34 defined between the interior sidewall of the processing chamber 10 and the wafer holder 20, and into the pump port 14. This gas flow, which is driven by the combination of the injection of gas downward from the openings 26 of the showerhead 12 and the draw of the vacuum pump 28 on the pump port 14, is generally expected to carry particles or particulates produced by the plasma processing away from the surface of the semiconductor wafer 18, thus limiting contamination of that surface.

However, it is recognized herein that some of the particles or particulates can “rebound” from surfaces downstream of the semiconductor wafer 18, and these rebounding particles or particulates can travel in a direction generally opposite that of the gas flow, with at least some of the rebounding particles or particulates ending up adhering to the surface of the semiconductor wafer 18 as undesirable wafer contamination. Potential surfaces for producing such rebounds include, by way of nonlimiting illustrative example, inner surfaces of the lower portion of the processing chamber 10, surfaces of the wafer holder 20, the bellows 14, and/or so forth. Depending on the type of the vacuum pump 28, the pumping process itself can also produce rebounding particles. For example, if the vacuum pump 28 is a turbomolecular pump, then the rapidly rotating blades of the turbopump 28 can strike particles or particulates and cause them to rebound and ultimately land on the surface of the semiconductor wafer 18 as wafer contamination.

In various embodiments disclosed herein, the plasma screen 40 is designed to minimize the flow resistance imposed by the plasma screen 40 (or, equivalently, to maximize flow conductance of the plasma screen 40) while simultaneously providing an effective barrier to rebounding particles or particulates.

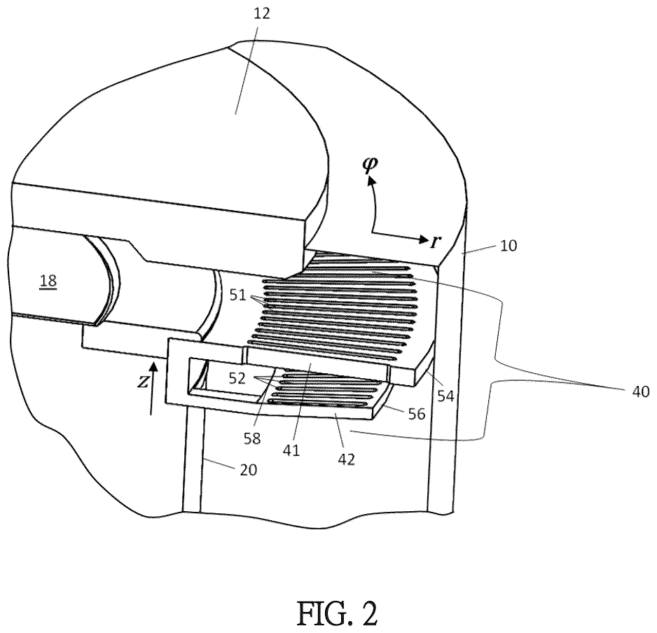

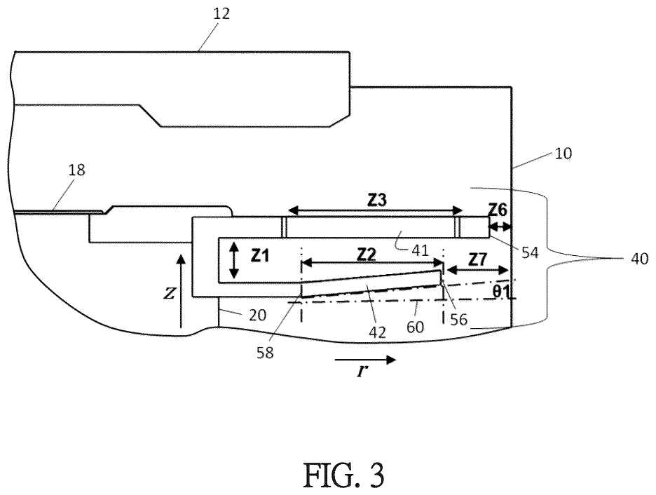

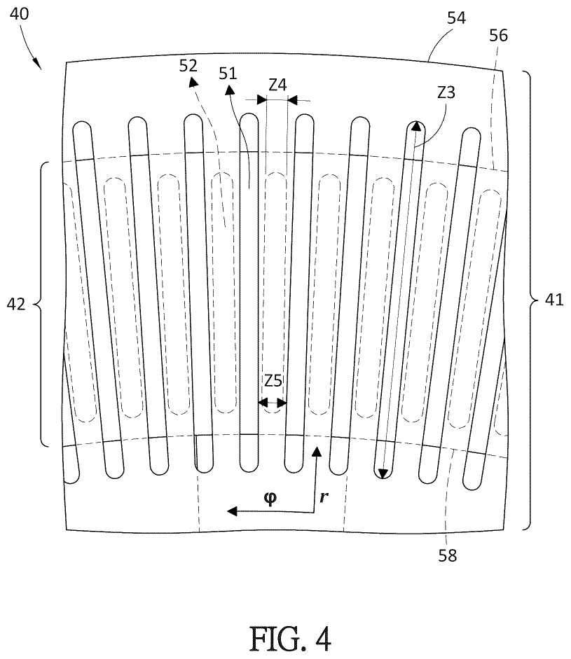

With continuing reference to FIG. 1 and with further reference now to FIGS. 2, 3, and 4, an illustrative embodiment of the plasma screen 40 which provides the benefits of low flow resistance (i.e., high flow conductance) and effective particle/particulate blocking is diagrammatically shown and described. FIG. 2 diagrammatically illustrates a perspective view of a portion of the plasma screen 40 of the semiconductor plasma processing tool of FIG. 1. FIG. 3 diagrammatically illustrates a cut view of a portion of the plasma screen 40 of the semiconductor plasma processing tool of FIG. 1. FIG. 4 diagrammatically illustrates a top view of a portion of the plasma screen 40 of the semiconductor plasma processing tool of FIG. 1. As seen in FIGS. 1-4, the illustrative plasma screen 40 includes first perforated screen 41 and a second perforated screen 42. The illustrative plasma screen 40 is an annular plasma screen, and hence the illustrative first perforated screen 41 is a first annular perforated screen 41, and likewise the second perforated screen 42 is a second annular perforated screen 42. Each of the first annular perforated screen 41 and the second annular perforated screen 42 is arranged concentrically with the central axis 32. That is, centers of the annuluses of the first and second annular perforated screens 41 and 42 coincides with points on the central axis 32. While annular plasma screens 41 and 42 are illustrated, in embodiments in which the semiconductor plasma processing tool does not have the illustrative generally cylindrical configuration with central axis 32, the first perforated screen and the second perforated screen may have correspondingly different geometry. (As another contemplated example, if the first and second perforated screens are located below the wafer holder they might be circular screens).

In more detail, in the illustrative example the first perforated screen 41 comprises an annular screen encircling the wafer holder 20, and likewise the second perforated screen 42 comprises an annular screen encircling the wafer holder 20. In the illustrative example the first and second annular perforated screens 41 and 42 are located at or near the top of the wafer holder 20, that is, at or near the inlet of the annular plenum 34, and as best seen in FIGS. 2 and 3 the width of at least the first annular perforated screen 41 along the radial direction r is large enough to be close to coinciding with the dimension along the radial direction r of the annular plenum 34 to provide effective screening. (As labeled in FIG. 3, in the illustrative example the outer edge of the first annular perforated screen 41 is spaced apart by a distance Z6 as will be discussed further hereinbelow). The second annular perforated screen 42 is arranged coaxially with and spaced apart (along the z direction) from the first annular perforated screen 41. In the illustrative example, perforations 51 of the first annular perforated screen 41 comprise first radial slots 51, and perforations 52 of the second annular perforated screen 42 comprise second radial slots 52. The slots 51 and 52 are radial slots as they extend along the radial direction r (put another way, the radial slots 51 and 52 are substantially longer along the radial direction r than along the direction perpendicular to the radial direction r). While radial slots 51 and 52 are employed in the illustrative embodiment, otherwise shaped perforations could be employed, such as round circular openings, square openings, and/or so forth.

To effectively block rebounding particles or particulates, in some embodiments the perforations 52 of the second perforated screen 42 are offset (i.e., staggered) from perforations 51 of the first perforated screen 41. This offset advantageously reduces or eliminates line-of-sight (i.e., straight line) trajectories via which rebounding particles or particulates could directly pass through the plasma screen 40 to potentially land on the surface of the semiconductor wafer 18 and form defects thereon. In the illustrative example, as best seen in the top view of a portion of the plasma screen 40 shown in FIG. 4, in the illustrative example this offset is achieved by arranging the second slots 51 of the second annular perforated screen 41 offset circumferentially (i.e., along the angular or azimuth direction φ) from corresponding first radial slots 51 of the first annular perforated screen 41.

As best seen in FIG. 3, in the illustrative plasma screen 40 the first annular perforated screen 41 is planar, with the plane of the first annular perforated screen 41 being transverse to the axial direction z as indicated in FIG. 3. An outer circumference 54 of the first annular perforated screen 41 is spaced apart from the inner wall of the processing chamber 10 by a distance Z6 labeled in FIG. 3. The second annular perforated screen 42 has a conical annular shape. In the illustrative example, the outer circumference 56 of the conical annular perforated screen 42 is closer to the first annular perforated screen 41 than an inner circumference 58 of the conical annular perforated screen 42. Note that the first and second annular perforated screens 41 and 42 along with these inner and outer circumferences 54, 56, and 58 are also labeled in the perspective view of FIG. 2 and in the top view of FIG. 4. The conical annular shape of the second annular perforated screen 42 is further characterized by a cone angle θ1 representing the tilt of the second annular perforated screen 42 respective to a plane 60 perpendicular to the axial direction z (or equivalently, respective to an r-z plane 60) as further labeled in FIG. 4. Note that since the plane 60 is parallel with the plane of the planar first annular perforated screen 41, it follows that the second annular perforated screen 42 is (at any given circumferential location) oriented at the angle θ1 respective to the first annular perforated screen 41. This advantageously tends to reduce the number of successive rebounds of a particle or particulate that rebounds by bouncing back-and-forth between the first and second annular perforated screens 41 and 42, thus reducing the likelihood that the rebounding particle or particulate will eventually pass along a generally upward trajectory through one of the first radial slots 51 so as to reach the surface of the semiconductor wafer 18 and form a defect thereon.

With continuing reference to FIG. 3, certain dimensions of the plasma screen 40 are labeled. A spacing in the axial direction z between the first annular perforated screen 41 and (the more distant inner circumference of) the second annular perforated screen 42 is labeled axial distance Z1. A length of the second annular perforated screen 42 in the radial direction r is labeled length Z2. A length of the first radial slots 51 of the first annular perforated screen 41 in the radial direction r is labeled in FIGS. 3 and 4 as length Z3. In some embodiments, the length Z3 of the first radial slots 51 is longer than a radial length of the second radial slots 52. Particularly referring to the top view of FIG. 4, a width of the second radial slots 52 of the second annular perforated screen 42 is labeled as width Z4. That is, the width Z4 is the width of the second radial slots 52 of the second annular perforated screen 42 in the direction transverse to the radial direction r (or, equivalently, along the circumferential direction φ locally at the slot). A spacing in the direction transverse to the radial direction r between edges of adjacent first radial slots 51 of the first annular perforated screen 41 is labeled as spacing Z5. That is, the spacing Z5 is the spacing of the first radial slots 51 of the first annular perforated screen 41 in the direction transverse to the radial direction r (or, equivalently, along the circumferential direction φ locally at the adjacent slots). A spacing in the radial direction r between the outer circumference 54 of the first annular perforated screen 41 from the inner wall of the processing chamber 10 is labeled in FIG. 3 as a spacing Z6. A spacing in the radial direction r between the outer circumference 56 of the second annular perforated screen 42 from the inner wall of the processing chamber 10 is labeled in FIG. 3 as a spacing Z7.

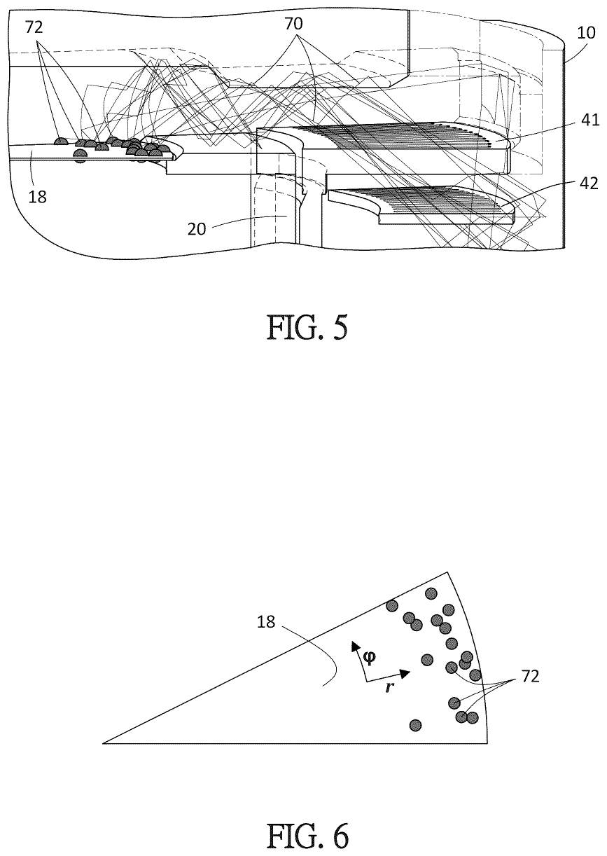

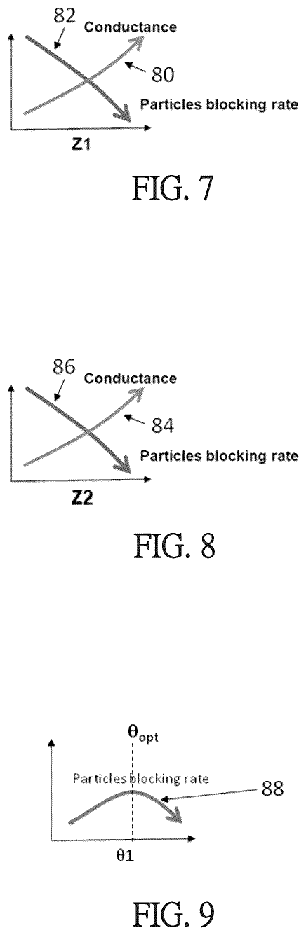

With reference now to FIGS. 5 and 6, (partial) blockage of rebounding particles or particulates by the plasma screen 40 comprising the first and second perforated screens 41 and 42 is diagrammatically shown. FIG. 5 diagrammatically illustrates a perspective view of a portion of the plasma screen 40, with diagrammatically shown representative paths 70 of some rebounding particles which land on a surface of the semiconductor wafer forming defects 72 on the semiconductor wafer. FIG. 6 diagrammatically illustrates a wedge portion of the semiconductor wafer 18, including these defects 72 formed by rebounding particles. As can be seen especially in FIG. 5, for a rebounding particle or particulate to land on the semiconductor wafer 18 thereby forming a defect 72, the path 70 of the rebounding particle or particulate must pass through one of the second radial slots 52 and then also through one of the first radial slots 51. Since the second slots 51 of the second annular perforated screen 41 are offset circumferentially from corresponding first radial slots 51 of the first annular perforated screen 41, the path 70 passing through both slots 51 and 52 has to be angled, making it less likely to reach the surface of the semiconductor wafer 18. The angle θ1 of the second annular perforated screen 42 respective to the first annular perforated screen 41 can advantageously further reduce the likelihood of rebounding particles or particulates reaching the semiconductor wafer 18, since any particles or particulates rebounding between the first and second annular perforated screens 41 and 42 will tend to be directed in a radial direction by the angle θ1. Nonetheless, as diagrammatically shown in FIGS. 5 and 6, some particles or particulates may be able to pass through both annular perforated screens 41 and 42 and reach the semiconductor wafer 18 to form defects 72.

While effectiveness in blocking rebounding particles or particulates is one advantage of the plasma screen 40, another advantage is low flow resistance imposed by the plasma screen 40 (or, equivalently, high flow conductance of the plasma screen 40). In general, a higher flow conductance (lower flow resistance) is advantageous for performance of the semiconductor plasma processing tool. For example, if the plasma screen introduces too much flow resistance (i.e., has too low flow conductance) then this can cause the etching or deposition to be performed at an undesirably high pressure, potentially leading to increased wafer defect counts and reduced device yield. The plasma screen 40 employing first and second annular perforated screens 41 and 42 can advantageously provide effective blocking of rebounding particles or particulates, while still providing a high flow conductance (low flow resistance) by way of the radial slots of relatively large area, while the offsetting of the second radial slots 52 of the second annular perforated screen 42 respective to the first radial slots 51 of the first annular perforated screen 41 reduces passthrough of rebounding particles or particulates.

The performance of the plasma screen 40 in achieving these advantages of high flow conductance and effective blocking of rebounding particles or particulates can be optimized by optimizing the geometry of the plasma screen 40, e.g., optimizing one or more of the parameters Z1, Z2, Z3, Z4, Z5. Z6, Z7, and/or θ1. Such optimization can be readily performed for a semiconductor plasma processing tool with a given geometry and/or configuration of the plasma processing chamber 10, showerhead 12, and pump port 14, and desired flow rates (or flow rate ranges) and other desired operating settings (or setting ranges) of the plasma etching or deposition process to be implemented. The flow conductance for a given geometry can be simulated using a computer-implemented fluid dynamics simulation, and/or by building prototypes with various geometries. The effectiveness of blocking rebounding particles or particulates can be simulated using a computer-implemented Monte Carlo simulation of a (possibly randomly generated) population of rebounding particles or particulates, and/or by building prototypes with various geometries. These are merely some nonlimiting illustrative approaches for optimizing the plasma screen 40 for deployment in a given semiconductor plasma processing tool.

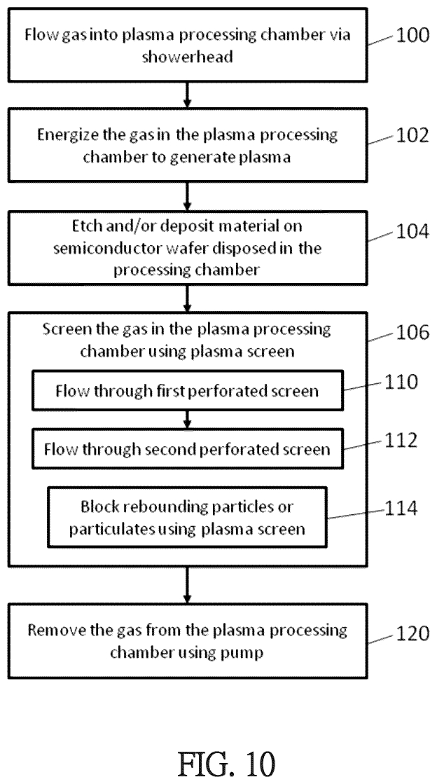

With reference now to FIGS. 7, 8, and 9, some illustrative simulation results are shown for optimizing the spacing Z1 between the first and second annular perforated screens 41 and 42, the length Z2 of the second annular perforated screen 42 in the radial direction r, and the angle θ1 of the second annular perforated screen 42 respective to the first annular perforated screen 41.

FIG. 7 diagrammatically shows a trendline 80 of flow conductance versus the spacing Z1 between the first and second annular perforated screens 41 and 42. As seen, the flow conductance 80 monotonically increases with increasing spacing between the first and second annular perforated screens 41 and 42. This reflects an increasingly large gap between the annular perforated screens 41 and 42 that facilitates gas flow through them. As previously noted, a higher flow conductance is generally advantageous—hence this performance metric is improved by increasing the spacing Z1 between the first and second annular perforated screens 41 and 42.

FIG. 7 also shows a trendline 82 of rebounding particle blocking rate versus the spacing Z1 between the first and second annular perforated screens 41 and 42. As seen, the particle blocking rate 82 monotonically decreases with increasing spacing between the first and second annular perforated screens 41 and 42. This reflects an increasingly large gap between the annular perforated screens 41 and 42 that facilitates passage of rebounding particles or particulates through the plasma screen 40. A higher blocking rate is advantageous since it reduces the number (or count) of particles or particulates that follow paths 70 and deposit as defects 72 on the semiconductor wafer 18 (see FIGS. 5 and 6 and related discussion). Hence, this performance metric is improved by decreasing the spacing Z1 between the first and second annular perforated screens 41 and 42.

Considering the two trendlines 80 and 82 respective to the spacing Z1 between the first and second annular perforated screens 41 and 42, it is apparent that a tradeoff exists between flow conductance (improved by increasing spacing Z1) and particle blocking rate (improved by decreasing spacing Z1). The spacing Z1 can thus be optimized for a given plasma processing process to obtain an optimal particle blocking rate while still providing an acceptable flow conductance.

FIG. 8 diagrammatically shows a trendline 84 of flow conductance versus length Z2 of the second annular perforated screen 42 in the radial direction r, and a trendline 86 of particle blocking rate versus length Z2 of the second annular perforated screen 42 in the radial direction r. Note that increasing the length Z2 of the second annular perforated screen 42 in the radial direction r is also assumed to increase the radial length of the second radial slots 52. Put another way, the length of the second radial slots 52 is assumed (i.e., modeled) to increase proportionally with the length Z2 of the second annular perforated screen 42.

As seen in FIG. 8, the flow conductance 84 monotonically increases with increasing length Z2 of the second annular perforated screen 42. This reflects the increasing length of the second radial slots 52 imposing less flow resistance (hence, higher flow conductance). As previously noted, a higher flow conductance is generally advantageous-hence this performance metric is improved by increasing the radial length Z2 of the second annular perforated screen 42 (again, assuming the radial lengths of the second radial slots 52 increase proportionally).

FIG. 8 also shows the trendline 86 of rebounding particle blocking rate versus length Z2 of the second annular perforated screen 42. As seen, the particle blocking rate 86 monotonically decreases with increasing length Z2 of the second annular perforated screen 42. This reflects the increasing length of the second radial slots 52 making the area of the second radial slots 52 larger, thereby imposing less of a barrier to rebounding particles or particulates. A higher blocking rate is advantageous since it reduces the number (or count) of particles or particulates that follow paths 70 and deposit as defects 72 on the semiconductor wafer 18 (see FIGS. 5 and 6 and related discussion). Hence, this performance metric is improved by decreasing the radial length Z2 of the second annular perforated screen 42 (again, assuming the radial lengths of the second radial slots 52 decrease proportionally).

Considering the two trendlines 84 and 86 respective to the radial length Z2 of the second annular perforated screen 42, it is apparent that a tradeoff exists between flow conductance (improved by increasing the radial length Z2 and thereby increasing the radial length of the second radial slots 52) and particle blocking rate (improved by decreasing the radial length Z2 and thereby decreasing the radial length of the second radial slots 52). The radial length Z2 of the second annular perforated screen 42 can thus be optimized for a given plasma processing process to obtain an optimal particle blocking rate while still providing an acceptable flow conductance.

FIG. 9 diagrammatically shows a trendline 88 of particle blocking rate versus the angle θ1 of the second annular perforated screen 42 respective to the first annular perforated screen 41. As seen, the particle blocking rate 88 initially increases with increasing angle θ1, but then reaches a peak at an angle θₒₚₜ, and thereafter the particle blocking rate 88 decreases with further increasing angle θ1. Since a goal of the design of the plasma screen 40 is to maximize the particle blocking rate, it follows that the optimal angle θ1 of the second annular perforated screen 42 respective to the first annular perforated screen 41 is the angle θₒₚₜ.

The analysis presented with reference to FIGS. 7, 8, and 9 is expected to capture typical trends of the flow conductance and particle blocking rate for the considered parameters Z1, Z2, and θ1. However, fluid dynamics simulation of the flow conductance and Monte Carlo simulation of the particle blocking can be performed for various geometries for a given semiconductor plasma processing tool to perform the optimization of these parameters and/or other parameters (e.g., Z3, Z4, Z5, Z6, and/or Z7). In some nonlimiting embodiments, some parameter ranges that are expected to provide a good combination of flow conductance and particle blocking rate for a flow rate of about 5000 sccm with a desired chamber conductance (argon gas) of about 120 sccm/mTorr are:
Angle θ1: 0°<θ1<30°;
Gap Z1: 9 mm<Z1<15 mm;
Length Z2: 0.3*Z3<Z2<Z3;
Second slot width Z4: 1 mm<Z4<Z5; and
Spacing Z6: 0 mm<Z6<Z7<30 mm.

Again, these are some nonlimiting illustrative ranges, and optimized values outside of these ranges are contemplated as may be indicated for a specific semiconductor plasma processing tool and plasma process by suitable fluid dynamic and/or Monte Carlo simulation optimization or the like.

The plasma screen 40 may be made of any suitable material that is resistant to excessive plasma damage. In a nonlimiting illustrative construction, the first annular perforated screen 41 may comprise hot anodizing aluminum (HAA), and the second annular perforated screen 42 may comprise quartz, yttrium oxide, yttrium oxyfluoride (YOF), another ceramic material, or another material with good plasma durability. Again, these are merely some nonlimiting illustrative examples.

With reference now to FIG. 10, a method of semiconductor plasma processing is shown by way of a flowchart. The method can, for example, be performed using the semiconductor plasma processing tool of FIG. 1, or using another suitable semiconductor plasma processing tool. In an operation 100, gas flows into a processing chamber 10 via a showerhead 12. In an operation 102, the gas in the processing chamber 10 is energized using RF and/or microwave energy to generate a plasma 16 in the processing chamber. In an operation 104, a semiconductor wafer disposed in the processing chamber 10 is etched, or material is deposited thereon, using the plasma 16. In an operation 106, the gas in the processing chamber 10 is screen using the a plasma screen 40. In one example, the screening 106 includes both an operation 110 of flowing the gas through first perforations 51 of a first perforated screen 41, and an operation 112 of flowing the gas through second perforations 52 of a second perforated screen 42. The screening 106 also includes an operation 114 in which rebounding particle or particulates are blocked by the plasma screen 40. In an operation 120, the gas is removed from the processing chamber 10 using a pump 28.

It should be noted that the flowchart of FIG. 10 diagrammatically depicts a typical sequence of operations performed on gas molecules during the semiconductor plasma processing. However, during the semiconductor plasma processing gas is continually flowing 100 into the processing chamber and being removed via the operation 120, and various portions of the gas in various portions of the interior of the processing chamber 10 are at any given time during the semiconductor plasma processing undergoing the various operations 102, 104, and 106. For example, a portion of the gas in the plasma region may be undergoing operation 102 to maintain the plasma 16 while simultaneously another portion of the gas (which has already been ionized) is performing the etching or deposition 104, while another portion of the gas in the vicinity of the plasma screen 40 is undergoing the screening operation 106, while another portion of the gas which has already passed through the plasma screen 40 is undergoing the removal by pumping 120.

In the following, some further embodiments are described.

In a nonlimiting illustrative embodiment, a semiconductor plasma processing tool includes a plasma processing chamber having a showerhead and a pump port, a wafer holder disposed in the plasma processing chamber, and a plasma screen disposed in the plasma processing chamber. The plasma screen includes a first perforated screen and a second perforated screen. In some embodiments, the perforations of the second perforated screen are offset from perforations of the first perforated screen. In some embodiments, the first perforated screen comprises a first annular perforated screen having a central axis, and the second perforated screen comprises a second annular perforated screen sharing the central axis with the first annular perforated screen and spaced apart along the central axis from the first annular perforated screen. In some annular embodiments, the perforations of the first annular perforated screen comprise first radial slots, and the perforations of the second annular perforated screen comprise second radial slots offset circumferentially from corresponding first radial slots of the first annular perforated screen. In some annular embodiments, the first annular perforated screen is planar, and the second annular perforated screen has a conical annular shape.

In a nonlimiting illustrative embodiment, a semiconductor plasma processing tool includes: a processing chamber including a showerhead and a pump port, the processing chamber configured to excite gas flowed into the processing chamber via the showerhead using radio frequency (RF) and/or microwave energy to form a plasma in the processing chamber; a wafer holder disposed in the processing chamber and configured to hold an associated semiconductor wafer; and an annular plasma screen encircling the wafer holder, the annular plasma screen including a first annular perforated screen and a second annular perforated screen.

In a nonlimiting illustrative embodiment, a method of semiconductor plasma processing includes: flowing gas into a processing chamber via a showerhead; energizing the gas in the processing chamber using RF and/or microwave energy to generate a plasma in the processing chamber that etches and/or deposits material on a semiconductor wafer disposed in the processing chamber; screening the gas in the processing chamber both by flowing the gas through first perforations of a first perforated screen and by flowing the gas through second perforations of a second perforated screen; and removing the gas from the processing chamber using a pump.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor plasma processing tool comprising:
a plasma processing chamber having a showerhead and a pump port;
a wafer holder disposed in the plasma processing chamber; and
a plasma screen disposed in the plasma processing chamber, the plasma screen including a first perforated screen and a second perforated screen.

2. The semiconductor plasma processing tool of claim 1, wherein perforations of the second perforated screen are offset from perforations of the first perforated screen.

3. The semiconductor plasma processing tool of claim 1, wherein:
the first perforated screen comprises a first annular perforated screen having a central axis; and
the second perforated screen comprises a second annular perforated screen sharing the central axis with the first annular perforated screen and spaced apart along the central axis from the first annular perforated screen.

4. The semiconductor plasma processing tool of claim 3, wherein:
perforations of the first annular perforated screen comprise first radial slots; and
perforations of the second annular perforated screen comprise second radial slots offset circumferentially from corresponding first radial slots of the first annular perforated screen.

5. The semiconductor plasma processing tool of claim 4, wherein the first radial slots are longer than the second radial slots.

6. The semiconductor plasma processing tool of claim 3, wherein:
the first annular perforated screen is planar; and
the second annular perforated screen has a conical annular shape.

7. The semiconductor plasma processing tool of claim 6, wherein an outer circumference of the second annular perforated screen is closer to the first annular perforated screen than an inner circumference of the second annular perforated screen.

8. The semiconductor plasma processing tool of claim 1, wherein:
the pump port comprises a bellows; and
the plasma screen is arranged upstream of the bellows and downstream of the showerhead along a flow path of gas flowing from the showerhead through the plasma processing chamber to the pump port.

9. The semiconductor plasma processing tool of claim 1, wherein the plasma processing chamber is a capacitively coupled plasma (CCP) processing chamber, an inductively coupled plasma (ICP) processing chamber, a transformer coupled plasma (TCP) processing chamber, or an electron cyclotron resonance (ECR) plasma processing chamber.

10. A semiconductor plasma processing tool comprising:
a processing chamber including a showerhead and a pump port, the processing chamber configured to excite gas flowed into the processing chamber via the showerhead using radio frequency (RF) and/or microwave energy to form a plasma in the processing chamber;
a wafer holder disposed in the processing chamber and configured to hold an associated semiconductor wafer; and
an annular plasma screen encircling the wafer holder, the annular plasma screen including a first annular perforated screen and a second annular perforated screen.

11. The semiconductor plasma processing tool of claim 10, wherein:
perforations of the first annular perforated screen comprise first radial slots; and
perforations of the second annular perforated screen comprise second radial slots offset circumferentially from corresponding first radial slots of the first annular perforated screen.

12. The semiconductor plasma processing tool of claim 11, wherein the first radial slots are longer than the second radial slots.

13. The semiconductor plasma processing tool of claim 11, wherein:
the first annular perforated screen is planar; and
the second annular perforated screen has a conical annular shape with its outer circumference closer to the first annular perforated screen than its inner circumference.

14. The semiconductor plasma processing tool of claim 10, wherein:
the pump port comprises a bellows.

15. The semiconductor plasma processing tool of claim 10, wherein the processing chamber is a capacitively coupled plasma (CCP) processing chamber, an inductively coupled plasma (ICP) processing chamber, a transformer coupled plasma (TCP) processing chamber, or an electron cyclotron resonance (ECR) plasma processing chamber.

16. A method of semiconductor plasma processing, the method comprising:
flowing gas into a processing chamber via a showerhead;
energizing the gas in the processing chamber using radio frequency (RF) and/or microwave energy to generate a plasma in the processing chamber that etches and/or deposits material on a semiconductor wafer disposed in the processing chamber;
screening the gas in the processing chamber both by flowing the gas through first perforations of a first perforated screen and by flowing the gas through second perforations of a second perforated screen; and
removing the gas from the processing chamber using a pump.

17. The method of claim 16, wherein:
the first perforated screen comprises a first annular perforated screen;
the second perforated screen comprises a second annular perforated screen;
the first perforations of the first annular perforated screen comprise first radial slots; and
the second perforations of the second annular perforated screen comprise second radial slots offset circumferentially from corresponding first radial slots of the first annular perforated screen.

18. The method of claim 17, wherein:
the first annular perforated screen is disposed closer to the showerhead than the second annular perforated screen; and
the first radial slots are longer than the second radial slots.

19. The method of claim 16, wherein:
the first perforated screen is closer to the showerhead than the second perforated screen;
the first perforated screen comprises a first annular perforated screen which is planar; and
the second perforated screen comprises a second annular perforated screen having a conical annular shape with its outer circumference closer to the first annular perforated screen than its inner circumference.

20. The method of claim 10, wherein the energizing of the gas in the processing chamber using RF and/or microwave energy to generate the plasma in the processing chamber includes coupling RF and/or microwave energy to the gas capacitively or inductively or using a transformer or by electron cyclotron resonance.
